(19) United States
(12) Patent Application Publication
(10) Pub. No.: US 2025/0194392 A1
(43) Pub. Date: Jun. 12, 2025

(54) APPARATUS AND METHOD OF MANUFACTURING DISPLAY DEVICE

(71) Applicant: Samsung Display Co., LTD., Yongin-si (KR)

(72) Inventors: Cheongwan MIN, Yongin-si (KR); Jungwoong BYUN, Yongin-si (KR); Dohun LEE, Yongin-si (KR); Jaihyuk CHOI, Yongin-si (KR); Myungsoo HUH, Yongin-si (KR)

(21) Appl. No.: 18/885,117

(22) Filed: Sep. 13, 2024

(30) Foreign Application Priority Data
Dec. 7, 2023 (KR) 10-2023-0176772

(51) Int. Cl. H10K 71/10; H10K 59/12; H10K 71/13

(52) U.S. Cl. CPC H10K 71/191; H10K 59/1201; H10K 71/135

(57) ABSTRACT

A method of manufacturing a display device includes: placing a display substrate on a stage; generating a first area image by photographing, by a vision portion arranged to face the display substrate, a first pixel area of the display substrate; finely adjusting, based on the first area image, a head portion to be aligned with a center of the first pixel area; discharging, by the head portion, ink to the first pixel area; generating, by the vision portion, a second area image by photographing a second pixel area of the display substrate; and finely adjusting, based on the second area image, the head portion to be aligned with a center of the second pixel area.

This application claims priority to Korean Patent Application No. 10-2023-0176772, filed on Dec. 7, 2023, and all the benefits accruing therefrom under 35 U.S.C. § 119, the content of which in its entirety is herein incorporated by reference.

### BACKGROUND

### 1. Field

One or more embodiments relate to an apparatus and method of manufacturing a display device, and more particularly, to an apparatus and method of manufacturing a display device, in which ink may be discharged to an accurate position.

### 2. Description of the Related Art

Mobility-based electronic devices have been widely used. In addition to compact electronic devices such as mobile phones, tablet personal computers (“PCs”) have recently been widely used as mobile electronic devices.

Such a mobile electronic device includes a display device to provide a user with

various functions, that is, visual information such as an image or a video. The proportion of display devices in electronic devices is increasing, and a structure that is bendable to a certain angle from a flat state is under development.

A display device may include various layers formed through various processes. For example, a display device may include a layer including an organic material, and the layer including an organic material may be formed on a substrate through a process of discharging organic ink, for example, an inkjet printing process. To perform the inkjet printing process, an apparatus for manufacturing a display device may include a spray unit for discharging ink.

The aforementioned background technology is technical information possessed by the inventor for derivation of the present disclosure or acquired by the inventor during the derivation of the present disclosure, and is not necessarily prior art disclosed to the public before the application of the present disclosure.

### SUMMARY

Ink discharged from an apparatus for manufacturing a display device is desirable to be discharged to an accurate position on a display substrate. However, due to the thermal expansion of the display substrate and the like, even when ink discharge started at a set position, the ink discharge proceeds such that the set position is gradually misaligned with the display substrate.

One or more embodiments include an apparatus and method of manufacturing a display device in which ink may be discharged to an accurate position of a display substrate.

However, such an aspect is an example, and the problem to be solved by the disclosure is not limited thereto.

Additional aspects will be set forth in part in the description which follows and, in part, will be apparent from the description, or may be learned by practice of the presented embodiments of the disclosure.

According to one or more embodiments, a method of manufacturing a display device includes placing a display substrate on a stage, generating a first area image by photographing, by a vision portion arranged to face the display substrate, a first pixel area of the display substrate, finely adjusting, based on the first area image, a head portion to be aligned with a center of the first pixel area, discharging, by the head portion, ink to the first pixel area, generating, by the vision portion, a second area image by photographing a second pixel area of the display substrate, and finely adjusting, based on the second area image, the head portion to be aligned with a center of the second pixel area.

In an embodiment, the method may further include calculating the center of the first pixel area based on the first area image.

In an embodiment, the method may further include calculating a first position difference between a preset center of the vision portion and the center of the first pixel area.

In an embodiment, the calculating of the first position difference may include calculating a first error in a first direction and a second error in a second direction perpendicular to the first direction, in a plan view.

In an embodiment, the head portion may be finely adjusted to move in the first direction as much as the first error and move in the second direction as much as the second error.

In an embodiment, the method may further include calculating the center of the second pixel area based on the second area image.

In an embodiment, the method may further include calculating a second position difference between a preset center of the vision portion and the center of the second pixel area.

In an embodiment, the second pixel area may be spaced apart from the first pixel area in the first direction, and the vision portion may be located in front of the head portion in the first direction.

In an embodiment, a relative location of the stage with respect to the vision portion and the head portion may change in the first direction.

According to one or more embodiments, an apparatus for manufacturing a display device includes: a stage on which a display substrate is placed; a body portion spaced apart from the stage to face the stage, wherein a relative location of the body portion with respect to the stage is changeable in a first direction; a vision portion disposed in the body portion and configured to photograph each of a plurality of pixel areas of the display substrate to generate an area image of each pixel area; an adjustment portion configured to finely adjust, based on the area image of each pixel area, a head portion to be aligned with a center of each pixel area; and the head portion connected to the adjustment portion and configured to discharge ink to each pixel area.

In an embodiment, the adjustment portion may be further configured to move the head portion three-dimensionally.

In an embodiment, the vision portion may be located in front of the head portion in the first direction.

In an embodiment, the vision portion may be provided in plurality and the plurality of vision portions may be arranged in parallel in a second direction perpendicular to the first direction.

In an embodiment, the head portion may be provided in plurality and the plurality of head portions may be arranged to correspond to the plurality of vision portions, respectively.

In an embodiment, the adjustment portion may be provided in plurality and the plurality of adjustment portions may be arranged to correspond to the plurality of vision portions, respectively.

In an embodiment, the vision portion may be disposed on a side surface of the body portion, and the head portion may be disposed on a lower surface of the body portion.

In an embodiment, the apparatus may further include a controller configured to calculate the center of each pixel area from the area image.

In an embodiment, the controller may be further configured to calculate a position difference between the center of each pixel area and a preset center of the vision portion.

In an embodiment, the adjustment portion may be further configured to finely adjust the head portion so that the position difference becomes zero.

In an embodiment, the position difference may include a first error in the first direction and a second error in a second direction perpendicular to the first direction, in a plan view.

Other aspects, features, and advantages than those described above will become apparent from the following drawings, claims, and detailed description of the disclosure

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of an apparatus for manufacturing a display device, according to an embodiment;

FIG. 2 is a schematic side view of an apparatus for manufacturing a display device, according to an embodiment;

FIGS. 3 to 6 are views schematically showing a method of manufacturing a display device, according to an embodiment;

FIG. 7 is a schematic plan view of a display device according to an embodiment; and

FIG. 8 is a schematic cross-sectional view of a display device manufactured by using an apparatus for manufacturing a display device, according to an embodiment, and may correspond to a cross-section of the display device taken along a line VIII-VIII′ of FIG. 7.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, embodiments will be described in detail with reference to the accompanying drawings, and in the description with reference to the drawings, the same or corresponding constituents are indicated by the same reference numerals and redundant descriptions thereof are omitted.

In the following embodiment, it will be understood that although the terms “first”, “second”, etc. may be used herein to describe various elements, these elements should not be limited by these terms. These elements are only used to distinguish one element from another.

In the following embodiment, as used herein, the singular forms “a,” “an,” and “the” are intended to include the plural forms as well, unless the context clearly indicates otherwise.

In the following embodiment, it will be further understood that the terms “comprises” and/or “comprising” used herein specify the presence of stated features or elements, but do not preclude the presence or addition of one or more other features or components.

In the following embodiment, it will be understood that when an element, such as a layer, a film, a region, or a plate, is referred to as being “on” another element, the element can be directly on the other element or intervening elements may be present thereon.

Sizes of elements in the drawings may be exaggerated for convenience of explanation. For example, since sizes and thicknesses of elements in the drawings are arbitrarily illustrated for convenience of explanation, the following embodiments are not limited thereto.

In the following embodiment, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

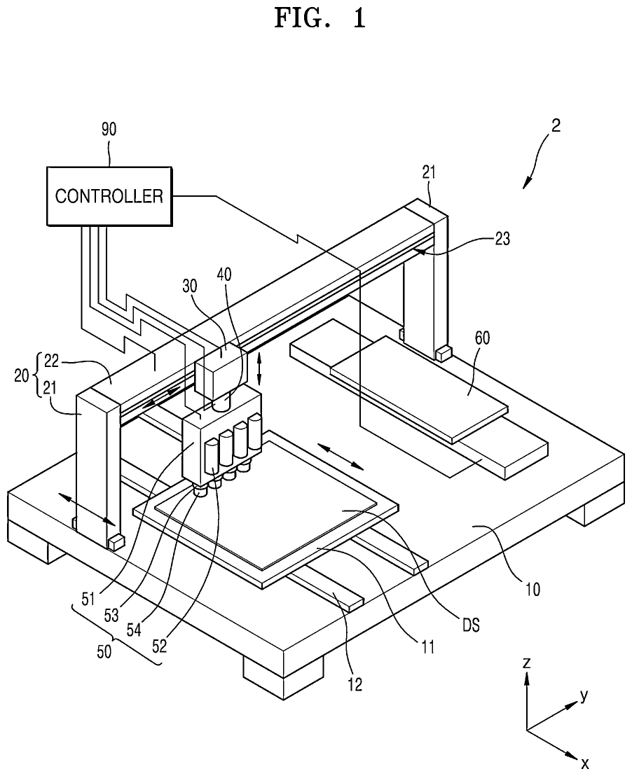

FIG. 1 is a schematic perspective view of an apparatus 2 for manufacturing a display device, according to an embodiment.

Referring to FIG. 1, the apparatus 2 for manufacturing a display device may include a support portion 10, a gantry 20, a first moving portion 30, a second moving portion 40, a spray unit 50, a maintenance and repair portion 60, and a controller 90.

In an embodiment, the support portion 10 may have, as an element on which other components are accommodated, a plane defined by a first direction (e.g., an x direction in FIG. 1) and a second direction (e.g., a y direction in FIG. 1) perpendicular to the first direction. Furthermore, in an embodiment, the support portion 10 may have a quadrangular plane, as illustrated in FIG. 1, but the disclosure is not limited thereto, and the support portion 10 may have various shapes, such as a polygonal shape, a circular shape, and the like.

A stage 11 may be further provided on the support portion 10. The stage 11 may be disposed on the support portion 10 and may have a plane defined by the first direction and the second direction. A display substrate DS may be placed on the stage 11, and the stage 11 may include an alignment mark (not shown) for aligning the display substrate DS. The display substrate DS, as a part of a display device being manufactured, may be a target to which the spray unit 50 discharges ink. In other words, as the discharged ink adheres to the display substrate DS, some layers of the display device may be formed. The stage 11 may form a work area of an inkjet printing process.

A guide portion 12 may be further provided between the support portion 10 and the stage 11. The guide portion 12 may be disposed on the support portion 10 and may be spaced apart from each other under the stage 11. For example, the guide portion 12 may include two guide portions spaced apart from each other in a second direction and adjacent to opposite side edges of the stage 11. The guide portions 12 may each extend in the first direction (e.g., a x direction), and the extension length of each of the guide portions 12 in the first direction may be greater than the length of the stage 11 in the first direction.

The guide portion 12 may guide the stage 11 to perform a linear motion in the extension direction of the guide portion 12. The guide portion 12 may include, for example, a linear motion rail.

In an embodiment, the stage 11 may linearly reciprocate along the guide portion

12. The stage 11 may manually perform a linear motion or automatically perform a linear motion by including a motor cylinder and the like. For example, the stage 11 may automatically perform a linear motion by including a linear motion block moving along the linear motion rail.

The gantry 20 may be disposed on the support portion 10 and may include a vertical member 21 and a horizontal member 22. Although FIG. 1 illustrates that the vertical member 21 and the horizontal member 22 each have a rectangular bar shape, the shapes of the vertical member 21 and the horizontal member 22 are not limited thereto.

The vertical member 21 of the gantry 20 may extend in a third direction (e.g., a z direction in FIG. 1) perpendicular to each of the first and second directions. The vertical member 21 may include, for example, two vertical members, which are arranged at opposite side edges of the support portion 10 with the stage 11 therebetween.

The horizontal member 22 of the gantry 20 may extend in the second direction between the vertical members 21. Opposite side end portions of the horizontal member 22 may be connected in an upper portion of each of the vertical members 21. The horizontal member 22 may define a first groove portion 23 therein extending the extension direction of the horizontal member 22, that is, the second direction (e.g., a y direction). The first groove portion 23 may be disposed on one side surface of the horizontal member 22. For example, the first groove portion 23 may be defined in a surface of the horizontal member 22 facing the first direction. The first groove portion 23 may guide the first moving portion 30 to linearly reciprocate in the extension direction of the first groove portion 23.

According to the above description, in an embodiment, the gantry 20 is fixed to the support portion 10 and the stage 11 moves in the first direction across the horizontal member 22 of the gantry 20, but the disclosure is not limited thereto. In another embodiment, while the stage 11 is fixed to the support portion 10, the gantry 20 may move on the support portion 10 in the first direction (e.g., a x direction). In other words, the gantry 20 and the stage 11 may move relative to each other in the first direction. In the following description, for convenience of explanation, as the gantry 20 and the stage 11 move relative to each other in the first direction, it is assumed that the gantry 20 moves in the first direction.

The first moving portion 30 may linearly move in the second direction. The first moving portion 30 may be movably connected to one side surface of the horizontal member 22 of the gantry 20. For example, the first moving portion 30 may be arranged on the surface of the horizontal member 22 where the first groove portion 23 is arranged. The first moving portion 30 may linearly reciprocate in the second direction along the first groove portion 23. In an embodiment, the first moving portion 30 may include a linear motor and the like.

In an embodiment, the second moving portion 40 may be arranged on one side surface of the first moving portion 30 and may linearly reciprocate in the third direction (e.g., a z direction). For example, the second moving portion 40 may be arranged on a lower surface of the first moving portion 30. The lower surface of the first moving portion 30 may be a surface of the first moving portion 30 facing the stage 11. In an embodiment, the second moving portion 40 may include a pneumatic cylinder and the like. Furthermore, the second moving portion 40 may rotate around an axis line extending in the third direction. To this end, the second moving portion 40 may include, for example, an electric motor, a pneumatic motor, and the like.

In an embodiment, the spray unit 50 may be arranged on a lower surface of the second moving portion 40. The spray unit 50 may move together as the first moving portion 30 and the second moving portion 40 move. In other words, the first moving portion 30 may transfer the spray unit 50 in the second direction (e.g., a y direction), and the second moving portion 40 may transfer the spray unit 50 in the third direction. For example, the movement range of the spray unit 50 may be substantially the same as the area of the support portion 10. The spray unit 50 may also be rotated by the second moving portion 40 around the axis line extending in the third direction.

The spray unit 50 may discharge ink droplets toward the display substrate DS. In this state, in an embodiment, the ink may include a polymer or low molecular weight organic material corresponding to an emission layer of an organic light-emitting display device. In another embodiment, the ink may include a liquid crystal, an alignment solution, or a red, green, or blue liquid obtained by mixing pigment particles in a solvent. In another embodiment, the ink may include a solution including an inorganic material particle including a quantum dot material and the like.

The maintenance and repair portion 60 may be disposed on the support portion 10 to be spaced apart from the stage 11 in the second direction. The maintenance and repair portion 60 may be arranged between the two vertical members 21 of the gantry 20. The maintenance and repair portion 60 may be a stage for maintenance and repair of the spray unit 50. In an embodiment, the maintenance and repair portion 60 may include an ink removal unit for removing ink remaining on the spray unit 50. Accordingly, an ink discharge defect occurring due to the ink remaining on the spray unit 50 may be prevented. The spray unit 50 may move in the second direction through the horizontal member 22 of the gantry 20 and move to the maintenance and repair portion 60.

The controller 90 may be electrically connected to the stage 11, the guide portion 12, the first moving portion 30, the second moving portion 40, and the spray unit 50. The controller 90 may control the position and operation of each component. Furthermore, the controller 90 may be electrically connected to the maintenance and repair portion 60 to control the operation of the maintenance and repair portion 60.

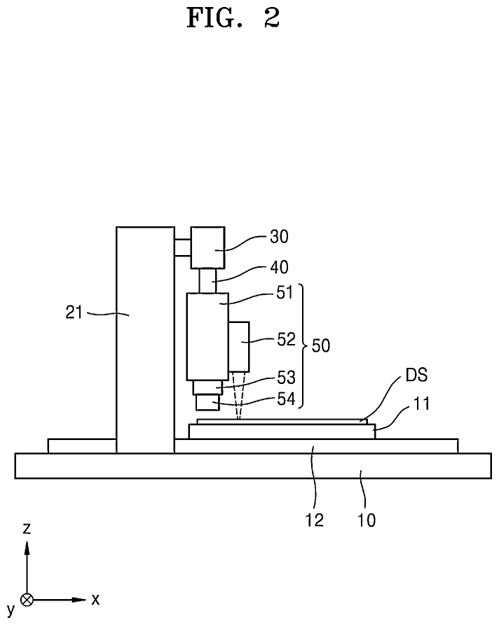

FIG. 2 is a schematic side view of the apparatus 2 for manufacturing a display device, according to an embodiment.

Referring to FIGS. 1 and 2, the spray unit 50 may include a body portion 51, a vision portion 52, an adjustment portion 53, and a head portion 54.

The vision portion 52, the adjustment portion 53, and the head portion 54 may be mounted on the body portion 51, and the body portion 51 may be connected to the second moving portion 40. The body portion 51 that is connected to the second moving portion 40 may linearly move in the second direction through the horizontal member 22 of the gantry 20. The body portion 51 may also linearly move in the third direction through the second moving portion 40. The body portion 51 may also be arranged to face the display substrate DS and may move relative to the display substrate DS in a first direction (e.g. an x direction in FIG. 2). In an embodiment, as described above, the stage 11 on which the display substrate DS is placed may be moved in the first direction. Alternatively, while the stage 11 on which the display substrate DS is placed is fixed, the gantry 20 may move in the first direction.

Although the body portion 51 may have a rectangular shape, as illustrated in FIGS. 1 and 2, the disclosure is not limited thereto.

The vision portion 52 may be arranged on one side surface of the body portion 51. In an embodiment, the vision portion 52 may be arranged on a surface of the body portion 51 facing the first direction (e.g. the x direction in FIG. 2). In an embodiment, the vision portion 52 may include a plurality of vision portions. The vision portions 52 may be arranged parallel to each other in a second direction (e.g. a y direction in FIG. 2) perpendicular to the first direction. The vision portions 52 may each generate an image by photographing the display substrate DS. The vision portions 52 may be any device having a photographing such as various kinds of cameras.

The adjustment portion 53 may be arranged on a lower surface of the body portion 51. The lower surface of the body portion 51 may refer to a surface of the body portion 51 facing the display substrate DS. In an embodiment, the adjustment portion 53 may include a plurality of adjustment portions. The adjustment portions 53 may be arranged parallel to each other in the second direction perpendicular to the first direction. In this state, the number of the adjustment portions 53 may correspond to the number of the vision portions 52, and the adjustment portions 53 may be arranged to correspond to the vision portions 52, respectively. For example, as illustrated in FIG. 2, when the vision portion 52 includes four vision portions, the adjustment portion 53 may include four adjustment portions. Furthermore, the vision portion 52 and the adjustment portion 53 corresponding to the vision portion 52 may be located at the same position in the second direction (e.g. the y direction in FIG. 2).

The adjustment portion 53 may finely adjust the head portion 54. In an embodiment, the adjustment portion 53 may finely adjust the head portion 54 in the first direction, the second direction perpendicular to the first direction, and a third direction (e.g. a z direction in FIG. 2) perpendicular to the first direction and the second direction.

The head portion 54 may be connected to the adjustment portion 53. The head portion 54 may be connected to a lower portion of the adjustment portion 53 and arranged to face the display substrate DS. In an embodiment, the head portion 54 may include a plurality of head portions. The head portions 54 may be arranged in the second direction perpendicular to the first direction (e.g., a x direction). In this state, the number of the head portions 54 may correspond to the number of the vision portions 52, and the head portions 54 may be arranged to correspond to the vision portions 52, respectively. For example, as illustrated in FIG. 2, when the vision portion 52 includes four vision portions, the head portion 54 may include four head portions. Furthermore, the vision portion 52 and the head portion 54 corresponding to the vision portion 52 may be located at the same position in the second direction. Furthermore, the vision portion 52 may be located in front of the head portion 54 in the first direction. Accordingly, when the body portion 51 moves in the first direction relative to the display substrate DS, the vision portion 52 may photograph one point of the display substrate DS ahead of the head portion 54, and based on an image of the point photographed by the vision portion 52, the head portion 54 may discharge ink to one point of the display substrate DS. Furthermore, as the discharged ink adheres to the display substrate DS, some layers of the display device may be formed.

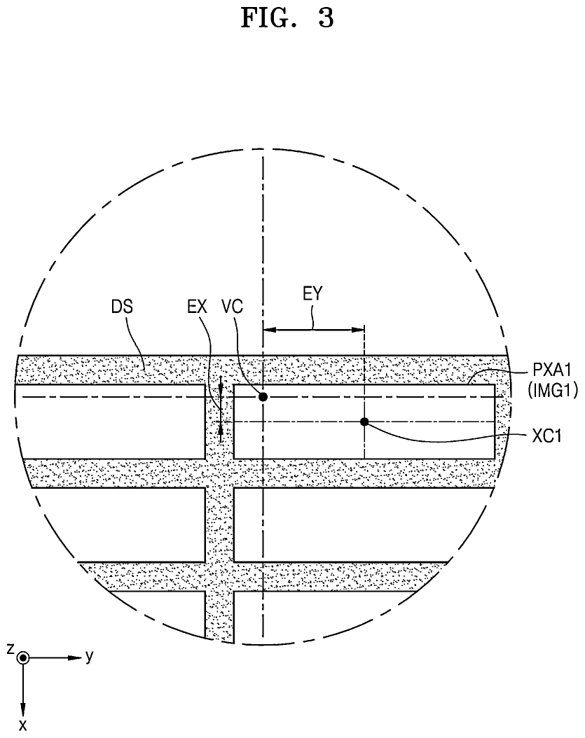

FIGS. 3 to 6 are views schematically showing a method of manufacturing a display device, according to an embodiment. Although the method of manufacturing a display device may use the apparatus 2 for manufacturing a display device described above as an embodiment, the disclosure is not limited thereto.

Referring to FIG. 3, a photographing area of one of the vision portions 52 is illustrated. In the following description, the one of the vision portions 52 is mainly described.

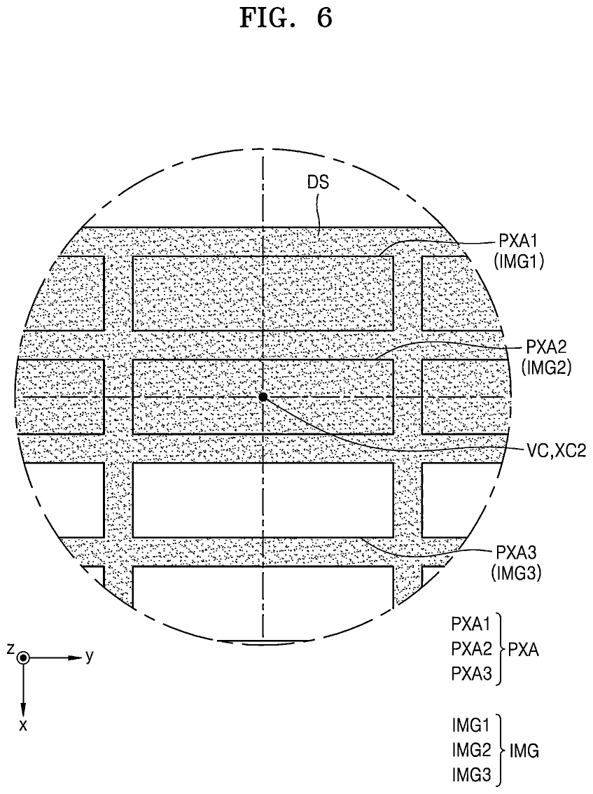

As described above, the display substrate DS may be placed on the stage 11. In this state, before the spray unit 50 starts to move to discharge ink, the vision portion 52 may photograph the display substrate DS. In this state, a center VC of the vision portion 52 may be set in the photographing area of the vision portion 52. The center VC of the vision portion 52 may be a preset point placed in the middle of the photographing area of the vision portion 52. The center VC of the vision portion 52 may be used to be aligned with a pixel area PXA (see FIG. 6) of the display substrate DS.

In an embodiment, the vision portion 52 may photograph the pixel area PXA, for example, a first pixel area PXA1 that is first arranged in one end portion of the display substrate DS. The pixel area PXA may refer to an area where a pixel is arranged. In other words, the pixel area PXA may refer to an opening area in which an emission layer may be arranged.

Furthermore, the vision portion 52 may generate an area image IMG by photographing the pixel area PXA. For example, the vision portion 52 may generate a first area image IMG1 by photographing the first pixel area PXA1.

The controller 90 may calculate a center of the pixel area PXA in the area image IMG. In detail, the controller 90 may measure, in the generated first area image IMG1, a length of the first pixel area PXA1 in a first direction (e.g. an x direction in FIG. 3) and a length of the first pixel area PXA1 in a second direction (e.g. a y direction in FIG. 3), and coordinate a center in the length in the first direction and a center in the length in the second direction, thereby calculating a center XC1 of the first pixel area PXA1.

Furthermore, the controller 90 may calculate a position difference between the center VC of the vision portion 52 and the center XC1 of the first pixel area PXA1. For example, the controller 90 may calculate an error EX in the first direction and an error EY in the second direction, in a plan view. As used herein, the “plan view” is a view in a z direction. For example, the error EX in the first direction (e.g. an x direction) may refer to a length difference in the first direction between the center XC1 of the first pixel area PXA1 and the center VC of the vision portion 52. The error EY in the second direction (e.g. an y direction) may refer to a length difference in the second direction between the center XC1 of the first pixel area PXA1 and the center VC of the vision portion 52.

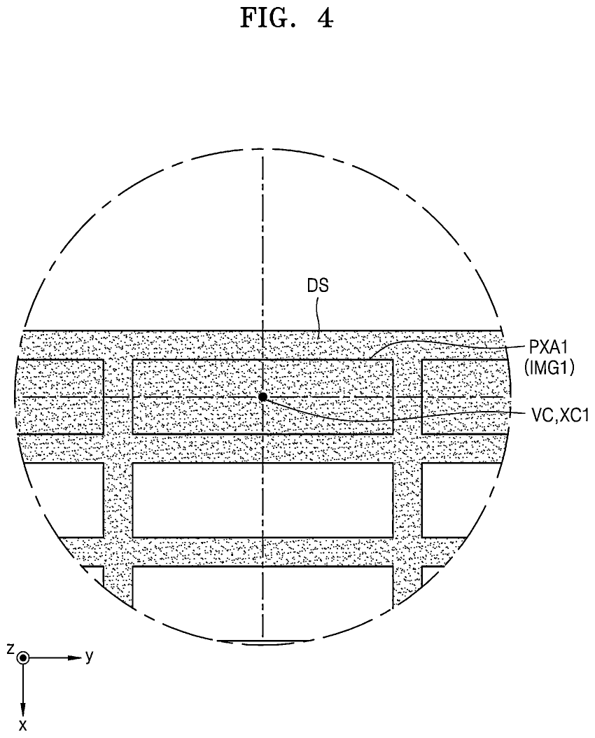

Referring to FIG. 4, the controller 90 may adjust a start position of the spray unit 50 based on the calculated position difference. In detail, by moving the body portion 51 in the second direction and/or in the first direction relative to the display substrate DS and/or the stage 11, the position of the spray unit 50 may be adjusted to match the center VC of the vision portion 52 with the center XC1 of the first pixel area PXA1. In other words, the spray unit 50, in particular, the head portion 54, may move as much as the error EX in the first direction, and as much as the error EY in the second direction so that the position difference becomes zero. Next, the head portion 54 may discharge ink toward the first pixel area PXA1. Accordingly, the spray unit 50, in particular, the head portion 54 and the display substrate DS, in particular, the pixel area PXA, are in an aligned state, and the head portion 54 may accurately discharge ink toward the first pixel area PXA1.

Furthermore, when the head portion 54 is in an aligned state with the first pixel area PXA1, as the stage 11 moves in a first direction (e.g. a −x direction in FIG. 4) or the gantry 20 moves in the first direction (e.g. an x direction in FIG. 4), that is, the gantry 20 moves in the first direction relative to the display substrate DS and/or the stage 11, the head portion 54 may be aligned again with a second pixel area PXA2 and may discharge ink toward the second pixel area PXA2.

In this case, when the start position of the spray unit 50 is appropriately aligned with the first pixel area PXA1, even when the gantry 20 moves in the first direction relative to the display substrate DS and/or the stage 11, the spray unit 50 may be appropriately aligned with other pixel areas PXAs. However, actually, due to the thermal expansion of the display substrate DS, an error in manufacturing a pixel area, and the like, even when the start position of the spray unit 50 is appropriately aligned, as the gantry 20 moves in the first direction relative to the display substrate DS and/or the stage 11, the alignment between the spray unit 50 and the pixel areas PXAs may be broken. A misalignment between the spray unit 50 and the pixel area PXA may prevent the head portion 54 from accurately discharging ink toward the pixel area PXA and may degrade the quality of the display substrate DS.

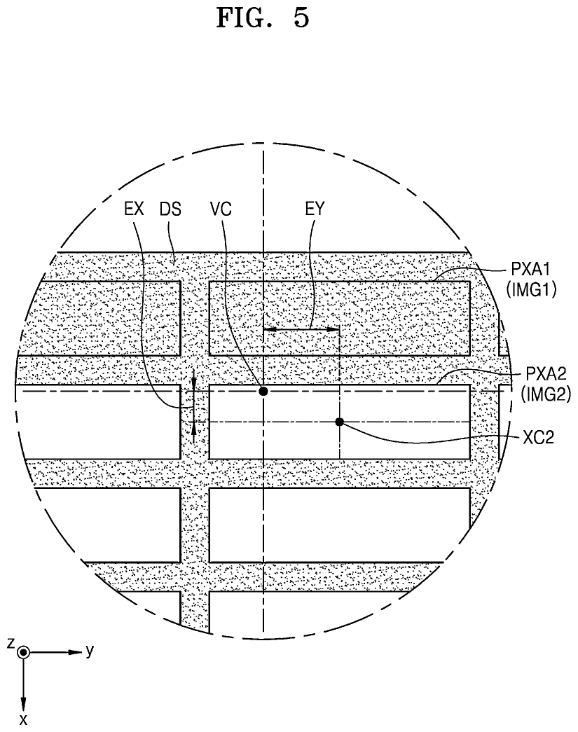

Referring to FIG. 5, according to an embodiment, the vision portion 52 may photograph the second pixel area PXA2. The second pixel area PXA2 may refer to a pixel area arranged adjacent to the first pixel area PXA1 in the first direction. Furthermore, the vision portion 52 may generate a second area image IMG2 by photographing the second pixel area PXA2.

The controller 90 may calculate a center XC2 of the second pixel area PXA2 in the generated second area image IMG2. Furthermore, the controller 90 may calculate a position difference between the center VC of the vision portion 52 and the center XC2 of the second pixel area PXA2. For example, the controller 90 may calculate the error EX in the first direction (e.g., a x direction) and the error EY in the second direction (e.g., a y direction), in a plan view.

Referring to FIG. 6, the controller 90 may operate the adjustment portion 53 corresponding to the vision portion 52, based on the calculated position difference. In other words, the head portion 54 may be finely adjusted through the adjustment portion 53. As the adjustment portion 53 finely moves three-dimensionally in the first direction (e.g., a x direction), the second direction (e.g., a y direction), and the third direction (e.g., a z direction), the head portion 54 connected to the adjustment portion 53 may be finely adjusted. The adjustment portion 53 may move the head portion 54 as much as the position difference between the center VC of the vision portion 52 and the center XC2 of the second pixel area PXA2, which is calculated by the controller 90, thereby allowing the head portion 54 to discharge ink at the center XC2 of the second pixel area PXA2. In other words, by the adjustment portion 53, the head portion 54 may be moved in the first direction (e.g., a x direction), as much as the error EX and in the second direction (e.g., a y direction) as much as the error EY. Next, the head portion 54 may discharge ink toward the second pixel area PXA2.

In a similar manner, the vision portion 52 may photograph a third pixel area PXA3. The third pixel area PXA3 may refer to a pixel area arranged adjacent to the second pixel area PXA2 in the first direction. Furthermore, the vision portion 52 may generate a third area image IMG3 by photographing the third pixel area PXA3.

The controller 90 may calculate a center XC3 of the third pixel area PXA3 in the generated third area image IMG3, and calculate a position difference by comparing the center XC3 of the third pixel area PXA3 with the center VC of the vision portion 52. Furthermore, the adjustment portion 53 may finely adjust again the head portion 54 to be aligned with the third pixel area PXA3 based on the position difference. The head portion 54 may discharge ink toward the third pixel area PXA3.

As such, according to an embodiment, the vision portion 52 may generate an area image by photographing each of the pixel areas PXAs each time. Furthermore, the controller 90 may calculate every time a misalignment distance of the pixel area PXA from the center VC of the vision portion 52 through the photographed area image. The adjustment portion 53 may finely adjust the head portion 54 every time as much as the calculated position difference, thereby allowing the head portion 54 to accurately discharge ink toward each pixel area PXA. Accordingly, printing quality may be effectively improved in the ink printing process, and thus, the quality of the display device may be improved.

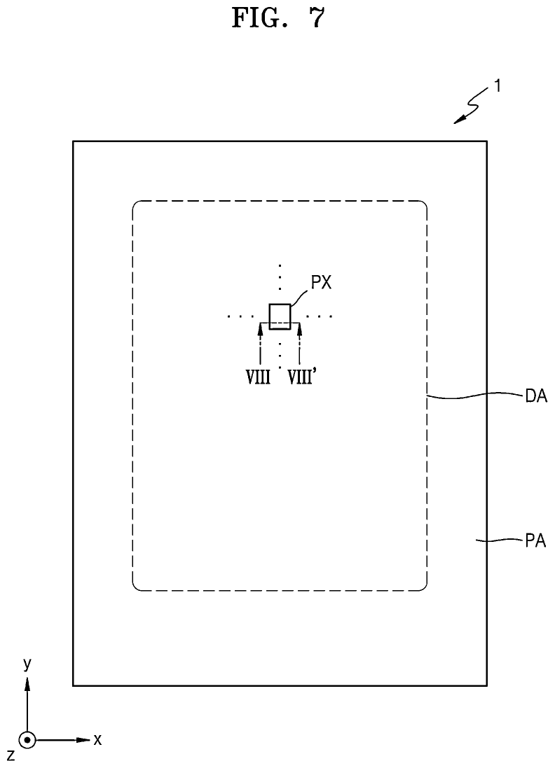

FIG. 7 is a schematic plan view of a display device 1 according to an embodiment. The display device 1 may be manufactured by using the apparatus and method of manufacturing a display device described above, but the disclosure is not limited thereto.

Referring to FIG. 7, the display device 1 manufactured according to an embodiment may include a display area DA and a peripheral area PA arranged outside the display area DA. The display device 1 may provide an image through an array of a plurality of pixels PX arranged two-dimensionally in the display area DA.

The peripheral area PA, which is an area that does not provide an image, may entirely or partially surround the display area DA. A driver and the like for providing an electrical signal or power to a pixel circuit corresponding to each of the pixels PX may be arranged in the peripheral area PA. A pad that is an area to which electronic components, printed circuit boards, and the like are electrically connected may be arranged in the peripheral area PA.

In the following description, the display device 1 is described to include an organic light-emitting diode (“OLED”) as a light-emitting element, but the display device 1 is not limited thereto. In another embodiment, the display device 1 may include a light-emitting display device including an inorganic light-emitting diode, that is, an inorganic light-emitting display device. The inorganic light-emitting diode may include a PN diode including an inorganic semiconductor-based material. When a voltage is applied to a PN junction diode in a forward direction, holes and electrons are injected, and the energy generated due to recombination of the holes and electrons is converted into light energy to thus emit light of a certain color. The inorganic light-emitting diode described above may have a width of several to hundreds of micrometers, and in some embodiments, the inorganic light-emitting diode may be referred to as a micro light-emitting diode (“LED”). In another embodiment, the display device 1 may be a quantum-dot light-emitting display device.

The display device 1 may be used as a display screen for various products, for example, not only portable electronic devices, such as mobile phones, smart phones, tablet personal computers (PC), mobile communication terminals, electronic organizers, electronic books, portable multimedia players (“PMP”), navigation devices, ultra-mobile PCs (“UMPC”), and the like, but also televisions, notebook computers, monitors, billboards, Internet of things (“IOT”) devices, and the like. Furthermore, the display device 1 according to an embodiment may be used for wearable devices, such as smart watches, watch phones, glasses-type displays, and head mounted displays (“HMD”). Furthermore, the display device 1 according to an embodiment may be used as an instrument panel of a vehicle, a center information display (“CID”) disposed in the center fascia or dashboard of a vehicle, a room mirror display in lieu of a side mirror of a vehicle, or a display screen disposed at the rear surface of a front seat as an entertainment device for a rear seat of a vehicle.

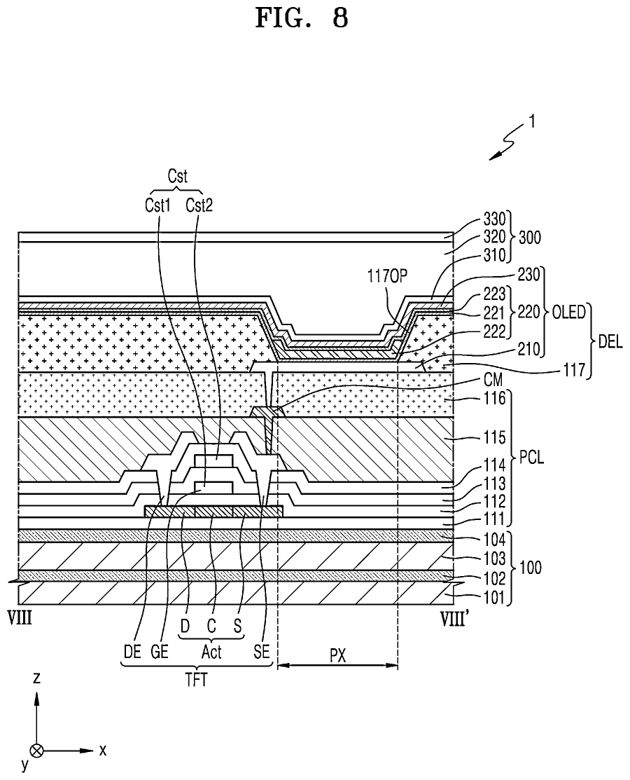

FIG. 8 is a schematic cross-sectional view of the display device 1 manufactured by using an apparatus for manufacturing a display device, according to an embodiment, and may correspond to a cross-section of the display device 1 taken along a line VIII-VIII′ of FIG. 7.

Referring to FIG. 8, the display device 1 may include a stack structure of a substrate 100, a pixel circuit layer PCL, a display element layer DEL, and an encapsulation layer 300.

The substrate 100 may have a multilayer structure including a base layer including polymer resin and an inorganic layer. For example, the substrate 100 may include a base layer including polymer resin and a barrier layer of an inorganic insulating layer. For example, the substrate 100 may include a first base layer 101, a first barrier layer 102, a second base layer 103, and a second barrier layer 104, which are sequentially stacked. The first base layer 101 and the second base layer 103 may each include polyimide (“PI”), polyethersulfone (“PES”), polyarylate, polyetherimide (“PEI”), polyethylene naphthalate (“PEN”), polyethylene terephthalate (“PET”), polyphenylene sulfide (“PPS”), polycarbonate (“PC”), cellulose triacetate (“TAC”), cellulose acetate propionate (“CAP”), or/and the like. The first barrier layer 102 and the second barrier layer 104 may each include an inorganic insulating material, such as a silicon oxide, a silicon oxynitride, and/or a silicon nitride. The substrate 100 may be flexible.

The pixel circuit layer PCL is disposed on substrate 100. FIG. 8 illustrates that the pixel circuit layer PCL includes a thin film transistor TFT, and a buffer layer 111, a first gate insulating layer 112, a second gate insulating layer 113, an interlayer-insulating layer 114, a first planarization insulating layer 115, and a second planarization insulating layer 116, which are disposed below or/and above components of the thin film transistor TFT.

The buffer layer 111 may reduce or prevent infiltration of foreign materials, moisture, or external air from under the substrate 100, and may provide a planarized surface onto the substrate 100. The buffer layer 111 may include an inorganic insulating material, such as a silicon oxide, a silicon oxynitride, and a silicon nitride, and may have a single layer or multilayer structure including the material described above.

The thin film transistor TFT on the buffer layer 111 may include a semiconductor layer Act, and the semiconductor layer Act may include polysilicon. Alternatively, the semiconductor layer Act may include amorphous silicon, an oxide semiconductor, an organic semiconductor, or the like. The semiconductor layer Act may include a channel region C, and a drain region D and a source region S, which are arranged at the opposite sides of the channel region C. A gate electrode GE may overlap the channel region C in a plan view.

The gate electrode GE may include a low resistance metal material. The gate electrode GE may include a conductive material including molybdenum (Mo), aluminum (Al), copper (Cu), titanium (Ti), and the like, and may be formed in a multilayer or single layer including the material described above.

The first gate insulating layer 112 between the semiconductor layer Act and the gate electrode GE may include an inorganic insulating material, such as a silicon oxide (SiO₂), a silicon nitride (SiNₓ), a silicon oxynitride (SiON), an aluminum oxide (Al₂O₃), a titanium oxide (TiO₂), a tantalum oxide (Ta₂O₅), a hafnium oxide (HfO₂), a zinc oxide (ZnO₂), or the like.

The second gate insulating layer 113 may be provided to cover the gate electrode GE. The second gate insulating layer 113, similar to the first gate insulating layer 112, may include an inorganic insulating material, such as SiO₂, SiNₓ, SiON, Al₂O₃, TiO₂, Ta₂O₅, HfO₂, ZnO₂, or the like.

An upper electrode Cst2 of a storage capacitor Cst may be disposed on the second gate insulating layer 113. The upper electrode Cst2 may overlap the gate electrode GE thereunder in a plan view. In this state, the gate electrode GE and the upper electrode Cst2 overlapping each other with the second gate insulating layer 113 therebetween may form the storage capacitor Cst. In other words, the gate electrode GE may function as a lower electrode Cst1 of the storage capacitor Cst.

As such, the storage capacitor Cst and the thin film transistor TFT may overlap each other. In some embodiments, the storage capacitor Cst does not overlap the thin film transistor TFT in a plan view.

The upper electrode Cst2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu, and may be formed in a single layer or multilayer including the material described above.

The interlayer-insulating layer 114 may cover the upper electrode Cst2. The interlayer-insulating layer 114 may include SiO₂, SiNₓ, SiON, Al₂O₃, TiO₂, Ta₂O₅, HfO₂, or ZnO₂, and the like. The interlayer-insulating layer 114 may include a single layer or multilayer including an inorganic insulating material described above.

A drain electrode DE and a source electrode SE may each be located on the interlayer-insulating layer 114. The drain electrode DE and the source electrode SE may be connected to the drain region D and the source region S through contact holes defined in insulating layers thereunder, respectively. The drain electrode DE and the source electrode SE may each include a material with excellent conductivity. The drain electrode DE and the source electrode SE may each include a conductive material including Mo, Al, Cu, Ti, and the like, and may be formed in a multilayer or single layer including the material described above. In an embodiment, the drain electrode DE and the source electrode SE may each have a multilayer structure of Ti/Al/Ti.

The first planarization insulating layer 115 may cover the drain electrode DE and the source electrode SE. The first planarization insulating layer 115 may include an organic insulating material, for example, a general purpose polymer, such as polymethylmethacrylate (“PMMA”) or polystyrene (“PS”), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and blends thereof.

The second planarization insulating layer 116 may be disposed on the first planarization insulating layer 115. The second planarization insulating layer 116 may include the same material as a material of the first planarization insulating layer 115, for example, a general purpose polymer, such as PMMA or PS, a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and blends thereof.

The display element layer DEL may be disposed on the pixel circuit layer PCL having the structure described above. The display element layer DEL may include the organic light-emitting diode OLED as a display element (i.e., a light-emitting element), and the organic light-emitting diode OLED may include a stack structure of a pixel electrode 210, an intermediate layer 220, and a common electrode 230. The organic light-emitting diode OLED may emit, for example, red, green, or blue light, or red, green, blue, or white light. The organic light-emitting diode OLED may emit light through an emission area, and the emission area may be defined as a pixel PX.

The pixel electrode 210 of the organic light-emitting diode OLED may be electrically connected to the thin film transistor TFT through contact holes defined in the second planarization insulating layer 116 and the first planarization insulating layer 115 and a contact metal CM disposed on the first planarization insulating layer 115.

The pixel electrode 210 may include a conductive oxide, such as an indium tin oxide (“ITO”), an indium zinc oxide (“IZO”), a zinc oxide (ZnO), an indium oxide (In₂O₃), an indium gallium oxide (“IGO”), or an aluminum zinc oxide (“AZO”). In another embodiment, the pixel electrode 210 may include a reflective film including Ag, Mg, Al, Pt, Pd, Au, Ni, Nd, Ir, Cr, or a compound thereof. In another embodiment, the pixel electrode 210 may further include a film formed of ITO, IZO, ZnO or In₂O₃ above/below the reflective film described above.

A pixel defining layer 117 defining an opening 117OP for exposing a central portion of the pixel electrode 210 is disposed on the pixel electrode 201. The pixel defining layer 117 may include an organic insulating material and/or an inorganic insulating material. The opening 117OP may define the emission area for the light emitted from the organic light-emitting diode OLED. For example, the size/width of the opening 117OP may correspond to the size/width of the emission area. Accordingly, the size and/or width of the pixel PX may depend on the size and/or width of the opening 117OP of the pixel defining layer 117 corresponding thereto.

The intermediate layer 220 may include an emission layer 222 corresponding to the pixel electrode 210. The emission layer 222 may include a polymer or low molecular weight organic material for emitting light of a certain color. Alternatively, the emission layer 222 may include an inorganic light-emitting material or quantum dots.

In an embodiment, the intermediate layer 220 may include a first functional layer 221 and a second functional layer 223, which are arranged below and above the emission layer 222, respectively. The first functional layer 221 may include, for example, a hole transport layer (“HTL”), or a hole transport layer and a hole injection layer (“HIL”). The second functional layer 223, as a component arranged above the emission layer 222, may include an electron transport layer (“ETL”) and/or an electron injection layer (“EIL”). The first functional layer 221 and/or the second functional layer 223 may be common layers formed to cover the entirety of the substrate 100, likewise the common electrode 230 to be described below.

The common electrode 230 may be on the pixel electrode 210 and may overlap the pixel electrode 210 in a plan view. The common electrode 230 may include a conductive material having a low work function. For example, the common electrode 230 may include a (semi-) transparent layer including Ag, Mg, Al, Pt, Pd, Au, Ni, Nd, Ir, Cr, lithium (Li), Ca, or an alloy thereof, and the like. Alternatively, the common electrode 230 may further include a layer including ITO, IZO, ZnO, or In₂O₃ on the (semi-) transparent layer including on the material described above. The common electrode 230 may be integrally formed to cover the entirety of the substrate 100.

The encapsulation layer 300 may be disposed on the display element layer DEL and may cover the display element layer DEL. The encapsulation layer 300 may include at least one inorganic encapsulation layer and at least one organic encapsulation layer, and in an embodiment, FIG. 8 illustrates that the encapsulation layer 300 includes a first inorganic encapsulation layer 310, an organic encapsulation layer 320, and a second inorganic encapsulation layer 330, which are sequentially stacked.

The first inorganic encapsulation layer 310 and the second inorganic encapsulation layer 330 may each include one or more inorganic materials, such as an aluminum oxide, a titanium oxide, a tantalum oxide, a hafnium oxide, a zinc oxide, a silicon oxide, a silicon nitride, and a silicon oxynitride. The organic encapsulation layer 320 may include a polymer-based material. The polymer-based material may include acrylic resin, epoxy-based resin, polyimide, polyethylene, and the like. In an embodiment, the organic encapsulation layer 320 may include acrylate. The organic encapsulation layer 320 may be formed by curing a monomer or applying a polymer. The organic encapsulation layer 320 may have transparency.

At least one of the layers forming the display device 1 may be formed through an inkjet printing process using the apparatus 2 for manufacturing a display device of FIG. 1.

According to the embodiments, a misalignment value between the display substrate and the spray unit may be calculated every time, and thus, ink may be discharged to an accurate position on the display substrate.

Accordingly, inkjet printing quality may be improved, and a display device with improved quality may be effectively implemented.

The effects of the disclosure are not limited to the above-described effects, and other various effects that are not described in the specification may be clearly understood from the following descriptions by one skilled in the art to which the present disclosure belongs.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of manufacturing a display device, the method comprising:
placing a display substrate on a stage;
generating a first area image by photographing, by a vision portion arranged to face the display substrate, a first pixel area of the display substrate;
finely adjusting, based on the first area image, a head portion to be aligned with a center of the first pixel area;
discharging, by the head portion, ink to the first pixel area;
generating, by the vision portion, a second area image by photographing a second pixel area of the display substrate; and
finely adjusting, based on the second area image, the head portion to be aligned with a center of the second pixel area.

2. The method of claim 1, further comprising calculating the center of the first pixel area based on the first area image.

3. The method of claim 2, further comprising calculating a first position difference between a preset center of the vision portion and the center of the first pixel area.

4. The method of claim 3, wherein the calculating of the first position difference comprises calculating a first error in a first direction and a second error in a second direction perpendicular to the first direction, in a plan view.

5. The method of claim 4, wherein the head portion is finely adjusted to move in the first direction as much as the first error and move the second direction as much as the second error.

6. The method of claim 1, further comprising calculating the center of the second pixel area based on the second area image.

7. The method of claim 6, further comprising calculating a second position difference between a preset center of the vision portion and the center of the second pixel area.

8. The method of claim 1, wherein the second pixel area is spaced apart from the first pixel area in the first direction, and the vision portion is located in front of the head portion in the first direction.

9. The method of claim 1, wherein a relative location of the stage with respect to the vision portion and the head portion changes in the first direction.

10. An apparatus for manufacturing a display device, the apparatus comprising:
a stage on which a display substrate is placed;
a body portion spaced apart from the stage to face the stage, wherein a relative location of the body portion with respect to the stage is changeable in a first direction;
a vision portion disposed in the body portion and configured to photograph each of a plurality of pixel areas of the display substrate to generate an area image of each pixel area;
an adjustment portion configured to finely adjust, based on the area image of each pixel area, a head portion to be aligned with a center of each pixel area; and
the head portion connected to the adjustment portion and configured to discharge ink to each pixel area.

11. The apparatus of claim 10, wherein the adjustment portion is further configured to move the head portion three-dimensionally.

12. The apparatus of claim 10, wherein the vision portion is located in front of the head portion in the first direction.

13. The apparatus of claim 10, wherein the vision portion is provided in plurality and the plurality of vision portions are arranged in parallel in a second direction perpendicular to the first direction.

14. The apparatus of claim 13, wherein the head portion is provided in plurality and the plurality of head portions are arranged to correspond to the plurality of vision portions, respectively.

15. The apparatus of claim 13, wherein the adjustment portion is provided in plurality and the plurality of adjustment portions are arranged to correspond to the plurality of vision portions, respectively.

16. The apparatus of claim 10, wherein the vision portion is disposed on a side surface of the body portion, and the head portion is disposed on a lower surface of the body portion.

17. The apparatus of claim 10, further comprising a controller configured to calculate the center of each pixel area from the area image.

18. The apparatus of claim 17, wherein the controller is further configured to calculate a position difference between the center of each pixel area and a preset center of the vision portion.

19. The apparatus of claim 18, wherein the adjustment portion is further configured to finely adjust the head portion so that the position difference becomes zero.

20. The apparatus of claim 18, wherein the position difference comprises a first error in the first direction and a second error in a second direction perpendicular to the first direction in a plan view.
